(19) United States
(12) Patent Application Publication
(10) Pub. No.: US 2025/0300004 A1
(43) Pub. Date: Sep. 25, 2025

(54) EPI-EPI DIELECTRIC TRENCH WALL

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/610,963

(22) Filed: Mar. 20, 2024

(51) Int. Cl. H01L 21/762; H01L 23/528; H01L 27/088; H01L 29/06; H01L 29/417; H01L 29/423; H01L 29/775; H01L 29/786

(52) U.S. Cl. CPC H01L 21/76224; H01L 23/5286; H10D 30/43; H10D 30/6735; H10D 30/6757; H10D 62/121; H10D 64/254; H10D 84/83

(57) ABSTRACT

A chip includes one or more first channels extending in a first direction, a first epitaxial (epi) layer coupled to the one or more first channels, one or more second channels extending in the first direction, a second epi layer coupled to the one or more second channels, and a dielectric wall disposed between the first epi layer and the second epi layer.

### BACKGROUND

### Field

Aspects of the present disclosure relate generally to chip layout, and more particularly, to epi-epi dielectric walls.

### Background

A chip includes many transistors for performing various functions on the chip. The transistors may be implanted using gate-all-around field effect transistors (GAAFETs), fin field effect transistors (FinFETs), and/or other types of transistors. With advances in semiconductor technology, there is a continuous demand to scale down the dimensions of the transistors and the spacing between the transistors to fit a large number of transistors on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes one or more first channels extending in a first direction, a first epitaxial (epi) layer coupled to the one or more first channels, one or more second channels extending in the first direction, a second epi layer coupled to the one or more second channels, and a dielectric wall disposed between the first epi layer and the second epi layer.

A second aspect relates to a method of fabricating a dielectric wall on a chip. The method includes etching a trench between a first epitaxial (epi) layer and a second epi layer from a backside of the chip, and filling the trench with a dielectric material.

### BRIEF DESCRIPTION OF THE DRAWINGS

FIG. 1A shows a side view of an example of a chip including a transistor and multiple topside layers according to certain aspects of the present disclosure.

FIG. 1B shows a perspective view of the transistor implemented with a gate-all-around FET according to certain aspects of the present disclosure.

FIG. 1C shows a side view of the chip of FIG. 1A further including multiple backside layers according to certain aspects of the present disclosure.

FIG. 1D shows a side view of the chip of FIG. 1C further including a via disposed between a backside contact and a backside metal layer according to certain aspects of the present disclosure.

FIG. 2A shows a top view of an example of a cell including a first transistor and a second transistor according to certain aspects of the present disclosure.

FIG. 2B shows a top view of an example of backside rails extending underneath the transistors of FIG. 2A according to certain aspects of the present disclosure.

FIG. 2C shows a cross-sectional view of a first epitaxial (epi) layer and a second epi layer of the transistors of FIG. 2A according to certain aspects of the present disclosure.

FIG. 2D shows a cross-sectional view of a shared gate and channels of the transistors of FIG. 2A according to certain aspects of the present disclosure.

FIG. 3 shows an example in which spacings between epi layers of FIG. 2A are reduced according to certain aspects of the present disclosure.

FIG. 4A shows dielectric walls isolating the epi layers of FIG. 3 according to certain aspects of the present disclosure.

FIG. 4B shows a cross-sectional view of the dielectric walls of FIG. 4A according to certain aspects of the present disclosure.

FIG. 4C shows a cross-sectional view of gates and channels of FIG. 4A according to certain aspects of the present disclosure.

FIG. 5A shows a cross-sectional view of epi layers formed on a semiconductor substrate according to certain aspects of the present disclosure.

FIG. 5B shows a cross-sectional view of the epi layers after most or all of the semiconductor substrate has been removed according to certain aspects of the present disclosure.

FIG. 5C shows a cross-sectional view in which trenches are etched between the epi layers from the backside of the chip according to certain aspects of the present disclosure.

FIG. 5D shows a cross-sectional view in which the trenches of FIG. 5C are filled with dielectric material to form dielectric walls between the epi layers according to certain aspects of the present disclosure.

FIG. 6A shows a cross-sectional view of gates according to certain aspects of the present disclosure.

FIG. 6B shows a cross-sectional view of a dielectric wall passing under the gates according to certain aspects of the present disclosure.

FIG. 7 is a flowchart illustrating a fabrication method according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

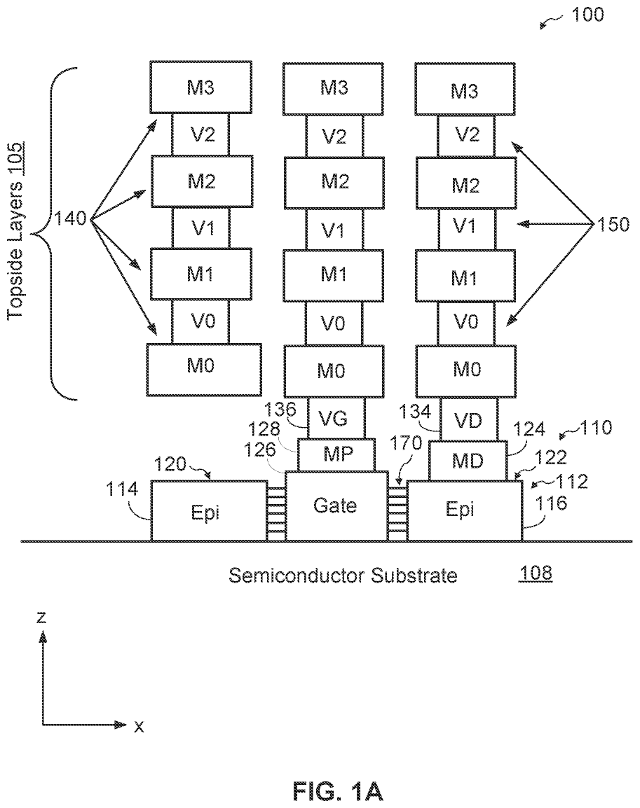

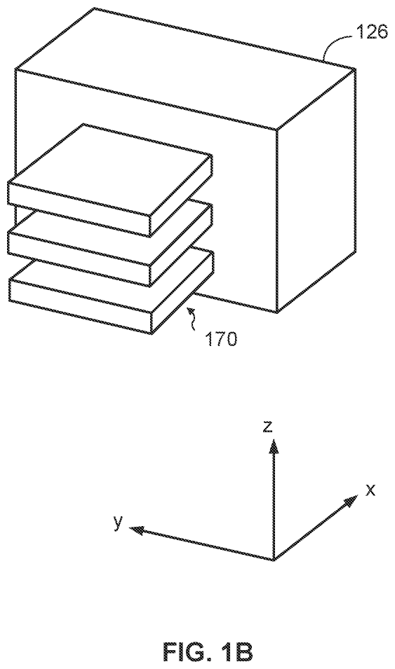

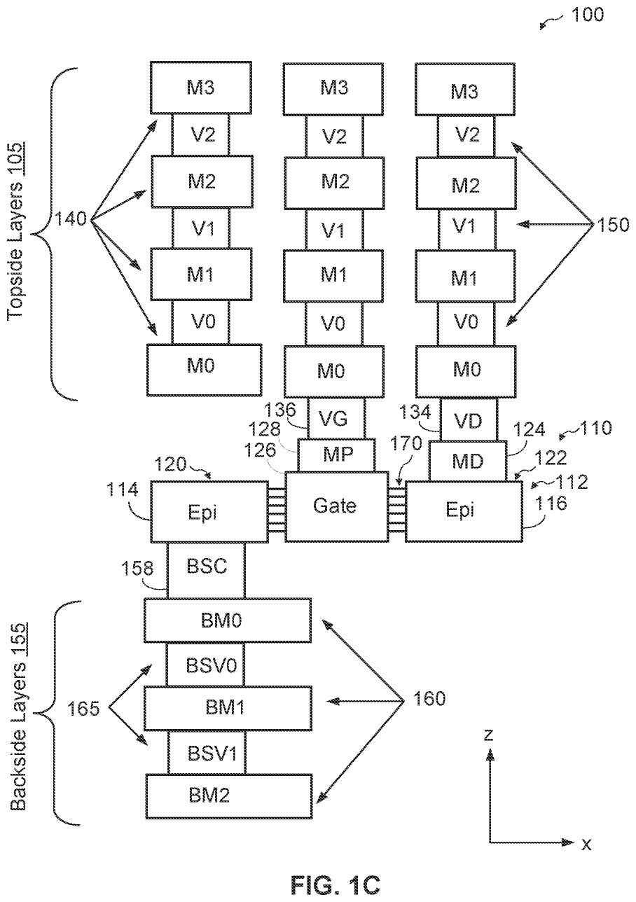

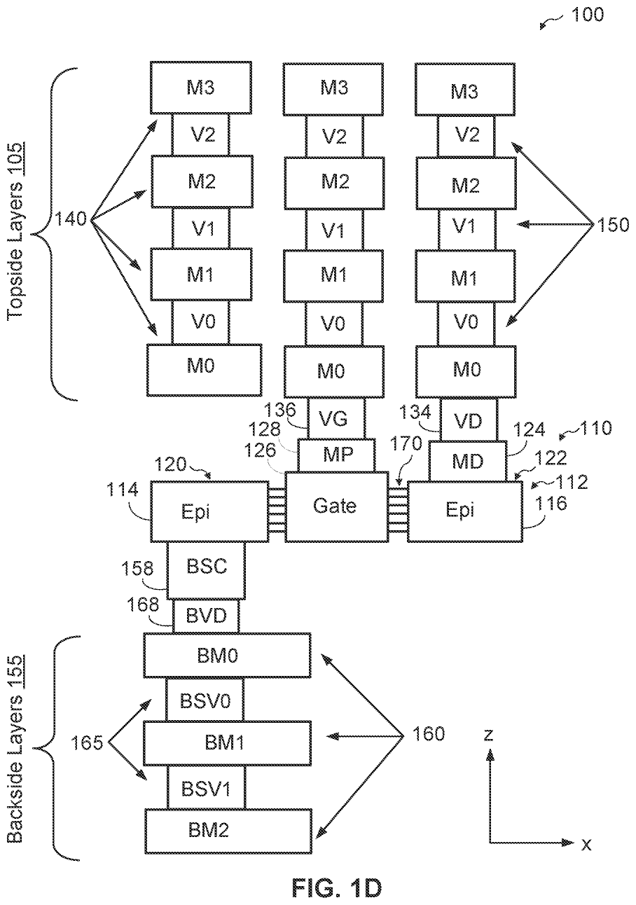

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon and/or another gate material. For a gate-all-around FET process, the diffusion region 112 includes channels 170 extending in the x direction in FIG. 1A, where the x direction is perpendicular to the z direction. In this example, the gate 126 may surround each of the channels 170 (also referred as ribbons) on four sides. In this regard, FIG. 1B shows a perspective view where each of the channels 170 is surrounded on four sides by the gate 126. For a finFET process, the diffusion region 112 includes fins (not shown) extending in the x direction where each fin may be surrounded on three sides by the gate 126. Each of the channels 170 may include a nanosheet, a nanowire, or the like.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the channels 170 on one side of the gate 126 to provide a first source/drain 120 and the second epi layer 116 is coupled to the channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown) between the gate 126 and each of the first epi layer 114 and the second epi layer 116.

In this example, the chip 100 includes a topside contact 124 formed on a top surface of the second source/drain 122. A top surface may also be referred to as a frontside surface. The contact 124 may be formed (i.e., patterned) from a topside contact layer using, for example, lithographic and etching processes. The contact 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations. A topside contact may also be referred to as a frontside contact or another term.

In this example, the topside layers 105 include topside metal layers 140. A topside metal layer may also be referred to as a frontside metal layer, a metal interconnect, or another term. The topside metal layers 140 may be patterned (e.g., using lithography and etching) to provide signal routing for the transistor 110 and other transistors (not shown in FIG. 1A) integrated on the chip 100. In some implementations, the topside metal layers 140 may also be patterned to form a power distribution network including supply rails for distributing power to the transistor 110 and other transistors integrated on the chip 100. In other implementations, the power distribution network is provided using backside layers (e.g., to reduce routing congestion in the topside layers 105), as discussed further below with reference to FIG. 1C.

In the example in FIG. 1A, the bottom-most topside metal layer among the topside metal layers 140 is referred to as metal layer M0. The topside metal layer immediately above metal layer M0 is referred to as metal layer M1, the topside metal layer immediately above metal layer M1 is referred to as metal layer M2, the topside metal layer immediately above metal layer M2 is referred to as metal layer M3, and so forth. Although four topside metal layers 140 (i.e., M0 to M3) are shown in FIG. 1A for ease of illustration, it is to be appreciated that the topside layers 105 may include additional topside metal layers above metal layer M3. It is to be appreciated that the present disclosure is not limited to the nomenclature in which the bottom-most topside metal layer is referred to as metal layer M0. For instance, in another example, the bottom-most topside metal layer may be referred to as metal layer M1 instead of metal layer M0.

The topside layers 105 also includes vias 150 that provide coupling between the topside metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. Also, in this example, the chip 100 includes a via 134 disposed between the contact 124 and metal layer M0, in which the via 134 couples the contact 124 to metal layer M0. In some implementations, the via 134 may be omitted with the contact 124 directly contacting metal layer M0.

In certain aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1C shows an example of backside layers 155 formed under the transistor 110. In this example, the backside layers 155 include backside metal layers 160. The backside metal layers 160 may be patterned (e.g., using lithography and etching) to form a power distribution network including supply rails for distributing power to the transistor 110 and other transistors on the chip 100.

In the example in FIG. 1C, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1C for ease of illustration, it is to be appreciated that the backside layers 155 may include additional metal layers below backside metal layer BM2.

In the example in FIG. 1C, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1C. In other implementations, the backside contact 158 may be coupled to backside metal layer BM0 through an intervening via. In this regard, FIG. 1D shows an example in which the chip 100 includes a backside via 168 (labeled “BVD”) disposed between the backside contact 158 and backside metal layer BM0. In this example, the via 168 provides a space between the backside contact 158 and backside metal layer BM0 in the z direction.

In the examples in FIG. 1C and FIG. 1D, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing.

Although one gate 126 is shown in FIGS. 1A, 1B, 1C, and 1D, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell.

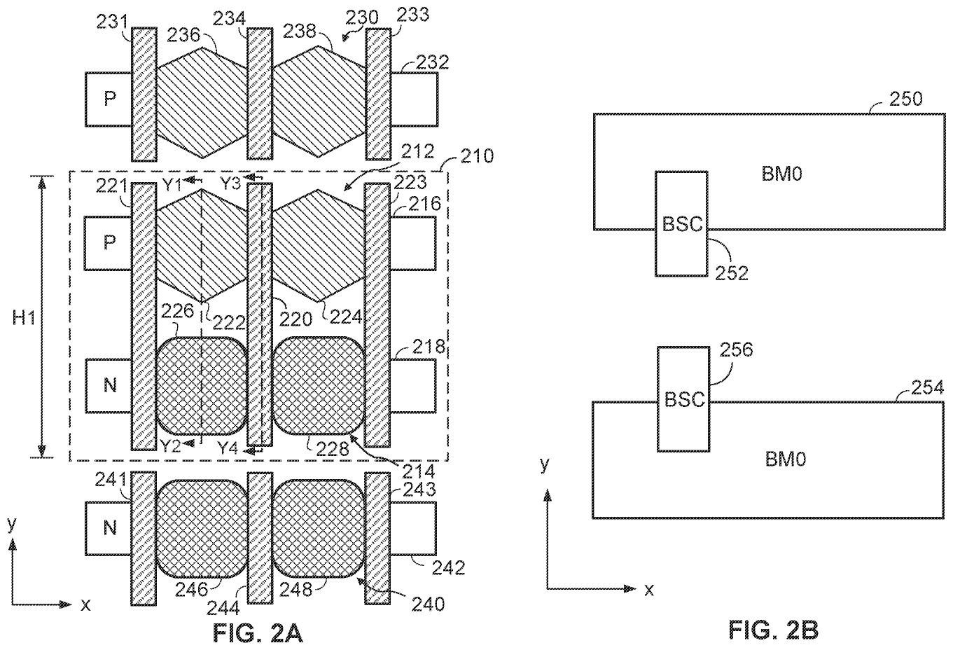

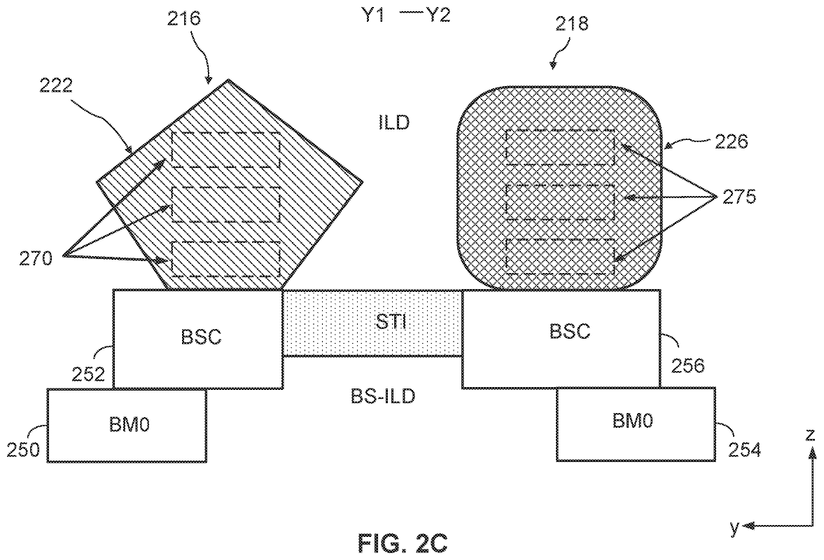

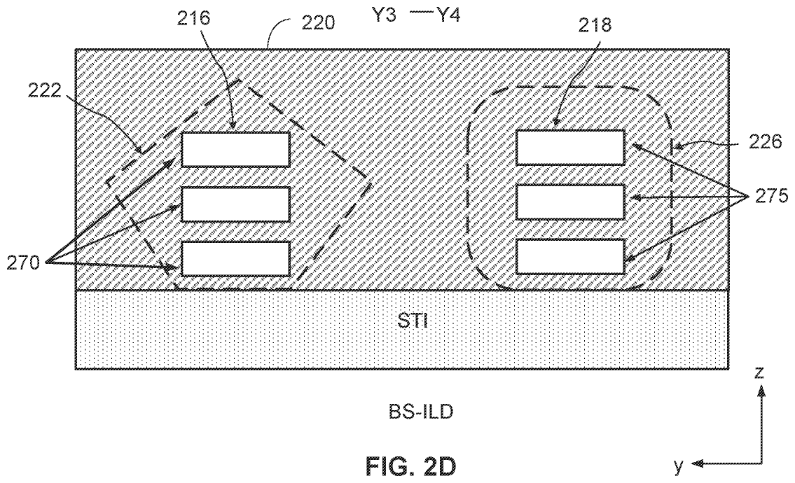

FIG. 2A shows a top view of an exemplary cell 210 integrated on the chip 100 according to certain aspects. In this example, the cell 210 includes a first diffusion region 216 extending in the x direction and a second diffusion region 218 extending in the x direction, in which the first diffusion region 216 and the second diffusion region 218 are spaced apart in the y direction, which is perpendicular to the x direction and the z direction. For a gate-all-around process, each of the diffusion regions 216 and 218 may include respective channels (e.g., a respective instance of the channels 170) extending in the x direction. For a finFET process, each of the diffusion regions 216 and 218 may include respective fins extending in the x direction. In this example, the first diffusion region 216 may be a p-type diffusion region and the second diffusion region 218 may be an n-type diffusion region (e.g., to provide the cell 210 with complementary transistors). However, it is to be appreciated that the present disclosure is not limited to this example.

The cell 210 includes a gate 220 extending in the y direction over the first diffusion region 216 and the second diffusion region 218. The gate 220 may include a metal (e.g., a high-k metal gate (HKMG)), polysilicon and/or another gate material. For a gate-all-around FET process, the gate 126 may surround each of the channels of the first diffusion region 216 on all four sides, and surround each of the channels of the second diffusion region 218 on all four sides (e.g., as illustrated in the example in FIG. 1B).

The first diffusion region 216 includes epitaxial (epi) layer 222, channels 270 (shown in FIG. 2D), and epi layer 224, and the second diffusion region 218 includes epi layer 226, channels 275 (shown in FIG. 2D), and epi layer 228. In the discussion below, the epi layer 222 is referred to as the first epi layer 222, the epi layer 226 is referred to as the second epi layer 226, the epi layer 224 is referred to as the third epi layer 224, and the epi layer 228 is referred to as the fourth epi layer 228. Each the first epi layer 222, the second epi layer 226, the third epi layer 224, and the fourth epi layer 228 may include epitaxially grown or deposited silicon, a silicon-based material (e.g., silicon-germanium), or any combination thereof. The gate 220 is disposed between the first epi layer 222 and the third epi layer 224, in which the channels 270 (shown in FIG. 2D) pass through the gate 220 and are coupled between the first epi layer 222 and the third epi layer 224. The gate 220 is also disposed between the second epi layer 226 and the fourth epi layer 228, in which the channels 275 (shown in FIG. 2D) pass through the gate 220 and are coupled between the second epi layer 226 and the fourth epi layer 228. The first epi layer 222 and the second epi layer 226 are spaced apart in the y direction, and the third epi layer 224 and the fourth epi layer 228 are spaced apart in the y direction, as shown in FIG. 2A.

In this example, the first diffusion region 216 and the gate 220 form a first transistor 212 (e.g., a p-type field effect transistor (PFET)), in which the first epi layer 222 and the third epi layer 224 provide sources/drains of the first transistor 212. The second diffusion region 218 and the gate 220 form a second transistor 214 (e.g., an n-type field effect transistor (NFET)), in which the second epi layer 226 and the fourth epi layer 228 provide sources/drains of the second transistor 214. In this example, the first transistor 212 and the second transistor 214 share the gate 220 (i.e., the gate 220 is common to both transistors 212 and 214). However, it is to be appreciated that the present disclosure is not limited to this example. For example, in other implementations, the gate 220 may be cut between the first diffusion region 216 and the second diffusion region 218 to provide separate gates for the transistors 212 and 214.

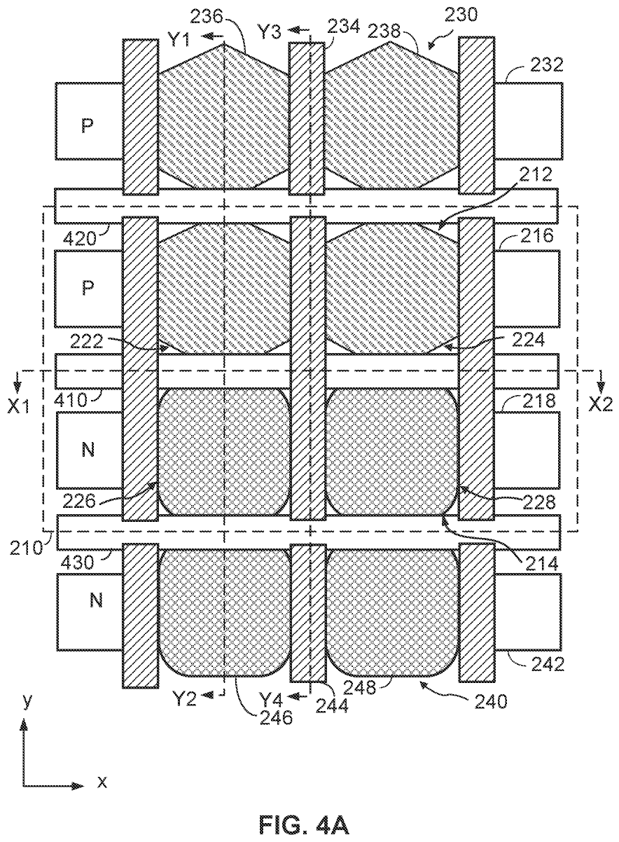

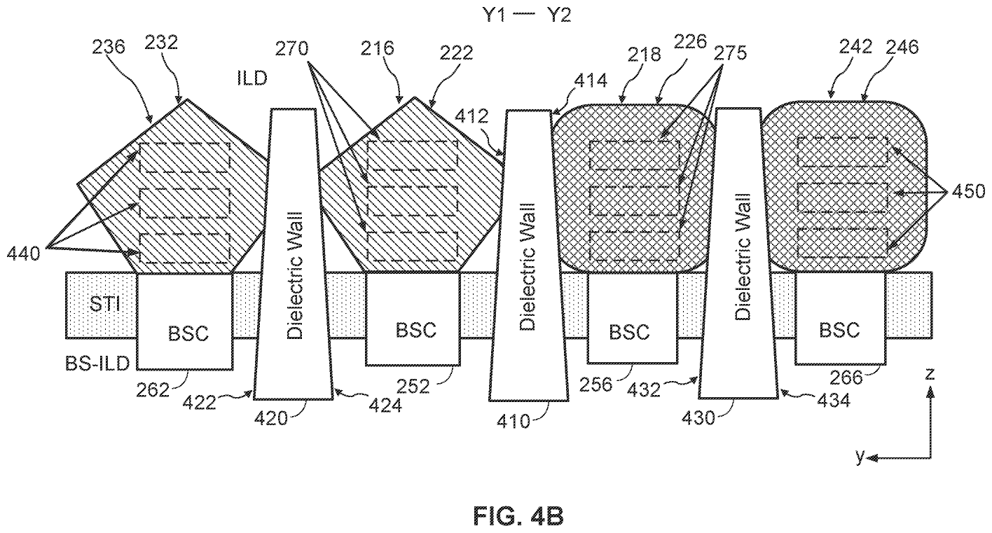

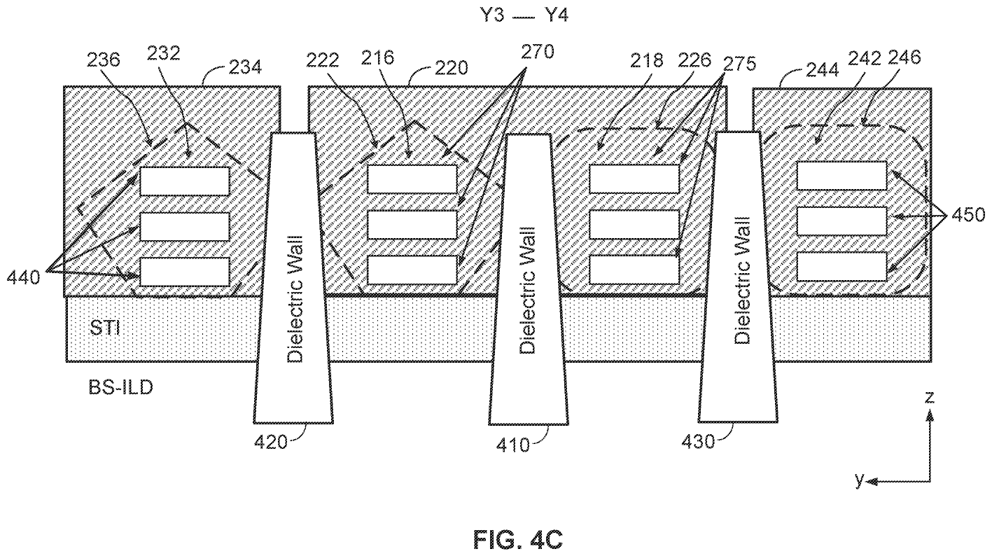

In this example, the chip 100 also includes a third diffusion region 232 extending in the x direction and a gate 234 extending in the y direction over the third diffusion region 232. The third diffusion region 232 includes a fifth epi layer 236, channels 440 (shown in FIG. 4C), and a sixth epi layer 238. The gate 234 is disposed between the fifth epi layer 236 and the sixth epi layer 238, in which the channels 440 pass through the gate 234 and are coupled between the fifth epi layer 236 and the sixth epi layer 238. In this example, the gate 234 and the third diffusion region 232 form a third transistor 230 (e.g., a PFET) located above the cell 210 in the y direction. The third transistor 230 may be part of a cell adjacent to the cell 210.

In this example, the chip 100 also includes a fourth diffusion region 242 extending in the x direction and a gate 244 extending in the y direction over the fourth diffusion region 242. The fourth diffusion region 242 includes a seventh epi layer 246, channels 450 (shown in FIG. 4C), and an eighth epi layer 248. The gate 244 is disposed between the seventh epi layer 246 and the eighth epi layer 248, in which the channels 450 pass through the gate 244 and are coupled between the seventh epi layer 246 and the eighth epi layer 248. In this example, the gate 244 and the fourth diffusion region 242 form a fourth transistor 240 (e.g., a NFET) located below the cell 210 in the y direction. The fourth transistor 240 may be part of a cell adjacent to the cell 210.

As shown in FIG. 2A, each epi layer extends beyond the respective diffusion region in the y direction. This is because the epitaxially process (e.g., epitaxially growth process) for each epi layer forms (e.g., grows) the epi layer in both the z and y directions.

In the example illustrated in FIG. 2A, the chip 100 includes additional gates 221, 223, 231, 233, 241, and 243 spaced apart from the gates 220, 234, and 244 in the x direction (e.g., at a uniform pitch). The additional gates 221, 223, 231, 233, 241, and 243 may be dummy gates (also known non-functional gates). In other implementations, the transistors 212, 214, 230, and 240 may be multi-gate transistors, and the additional gates 221, 223, 231, 233, 241, and 243 may be additional gates of the transistors 212, 214, 230, and 240. Although not shown in FIG. 4A, it is to be appreciated that the gate 220 may be spaced apart from the epi layers 222, 224, 226, and 228 in the x direction by thin spacers (not shown), the gate 234 may be spaced apart from the epi layers 236 and 238 in the x direction by thin spacers (not shown), and the gate 244 may be spaced apart from the epi layers 246 and 248 in the x direction by thin spacers (not shown).

Power may be distributed to the transistors 212, 214, 230, and 240 using backside layers (e.g., the backside layers 155). In this regard, FIG. 2B shows a top view of a first rail 250 and a second rail 254 formed from bottom metal layer BM0, which is below the transistors 212, 214, 230, and 240 show in FIG. 2A.

In this example, the first rail 250 extends in the x direction under the first transistor 212 and the third transistor and 230 shown in FIG. 2A. The first rail 250 is coupled to the backside of the first epi layer 222 through a first backside contact 252 disposed between the first epi layer 222 and the first rail 250. In this example, the first rail 250 may be a supply rail (also referred to as a power rail) for coupling a supply voltage to the first epi layer 222. In certain aspects, the first rail 250 is shared by the first transistor 212 and the third transistor 230. In these aspects, the first rail 250 may also be coupled to the fifth epi layer 236 by another backside contact (not shown).

In this example, the second rail 254 extends in the x direction under the second transistor 214 and the fourth transistor 240 shown in FIG. 2A. The second rail 254 is coupled to the backside of the second epi layer 226 through a second backside contact 256 disposed between the second epi layer 226 and the second rail 254. In this example, the second rail 254 may be a ground rail. In certain aspects, the second rail 254 is shared by the second transistor 214 and the fourth transistor 240. In these aspects, the second rail 254 may also be coupled to the seventh epi layer 246 by another backside contact (not shown).

It is to be appreciated that the present disclosure is not limited to the example shown in FIG. 2B. For example, in other implementations, the first rail 250 may be coupled to the third epi layer 224 by the first backside contact 252 and/or the second rail 254 may be coupled to the fourth epi layer 228 by the second backside contact 256. Although FIG. 2B shows an example where the first backside contact 252 and the second backside contact 256 are aligned in the x direction, it is to be appreciated that the first backside contact 252 and the second backside contact 256 may be spaced apart in the x direction in some implementations.

In this example, the first transistor 212 and the second transistor 214 in the cell 210 may be coupled to form a complementary inverter. For example, input signal routing in metal layer M0 may be coupled to the shared gate 220 by a gate via (e.g., via 136) to provide the input of the inverter, and output signal routing in metal layer M0 may be coupled the third epi layer 224 and the fourth epi layer 228 by a metal contact (e.g., contact 124) and a via (e.g., via 134) to provide the output of the inverter. However, it is to be appreciated that the cell 210 is not limited to an inverter.

FIG. 2C shows a cross-sectional view of the cell 210 taken along cross-section line Y1-Y2 in FIG. 2A, which intersects the first epi layer 222 and the second epi layer 226. In this example, the first diffusion region 216 and the second diffusion region 218 are formed using a gate-all-around FET process, but are not limited to this example. In this example, the first epi layer 222 is coupled to the channels 270 passing through the gate 220, and the second epi layer 226 is coupled to the channels 275 passing through the gate 220. Note that the gate 220 and the channels 270 and 275 are not intersected by the cross-section line Y1-Y2 in this example. In FIG. 2C, the channels 270 are shown in dashed line to indicate the position of the channels 270 in the z and y direction, and the channels 275 are shown in dashed line to indicate the position of the channels 275 in the z and y direction.

FIG. 2C shows an example in which the first epi layer 222 and the second epi layer 226 have different shapes. This may be due to, for example, the first epi layer 222 and the second epi layer 226 being formed using different epitaxial processes and/or materials. For example, the first epi layer 222 may include silicon-germanium (SiGe) and the second epi layer 226 may include silicon. However, it is to be appreciated that the present disclosure is not limited to this example. In other implementations, the first epi layer 222 and the second epi layer 226 may have substantially the same shape. Also, in other implementations, the first epi layer 222 may have a shape that is different from the exemplary shape shown in FIG. 2C and/or the second epi layer 226 may have a shape that is different from the exemplary shape shown in FIG. 2C.

In the example shown in FIG. 2C, the chip 100 may also include shallow trench isolation (STI) to provide additional isolation between transistors (e.g., the first transistor 212 and the second transistor 214) on the chip 100. However, it is to be appreciated that the STI may be omitted in some implementations. The chip 100 may also include an interlayer dielectric (ILD) between the epi layers 222 and 226, and a backside interlayer dielectric (BS-ILD) to provide isolation between rails and/or other structures formed in one or more of the backside metal layers (e.g., backside metal layer BM0).

FIG. 2D shows a cross-sectional view of the cell 210 taken along cross-section line Y3-Y4 in FIG. 2A. As shown in FIG. 2D, the channels 270 pass through the gate 220 and each of the channels 270 is surrounded by the gate 220 on four sides. The channels 275 pass through the gate 220 and each of the channels 275 is surrounded by the gate 220 on four sides. Note that the epi layers 222 and 226 are not intersected by the cross-section line Y3-Y4 in this example. In FIG. 2D, the first epi layer 222 is shown in dashed line to indicate the position of the first epi layer 222 in the z and y direction, and the second epi layer 226 is shown in dashed line to indicate the position of the second epi layer 226 in the z and y direction.

It is desirable to reduce the heights of cells on the chip 100 in order to fit a larger number of cells on the chip 100. Two obstacles to scaling down (i.e., reducing) cell height in advanced semiconductor processes include: 1) metal layer M0 pitch/resistance, and 2) minimum epi-epi spacing to avoid potential epi-epi shorts (e.g., a short between the first epi layer 222 and the second epi layer 226). The first obstacle can be relieved by the backside power distribution discussed above, which reduces congestion in metal layer M0 by moving power distribution to the backside.

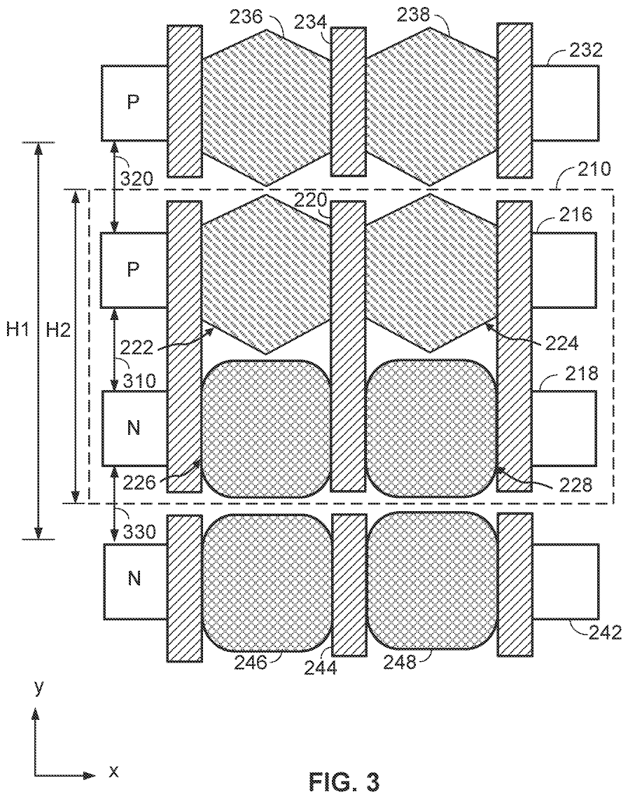

The second obstacle to scaling down cell height is illustrated in FIG. 3. In the example in FIG. 3, the spacing 310 between the first diffusion region 216 and the second diffusion region 218 in the cell 210 is reduced to reduce the height of the cell 210. Also, the spacing 320 between the first diffusion region 216 and the third diffusion region 232 is reduced, which reduces the height of the cell 210 by allowing the top boundary of the cell 210 to be moved closer to the first diffusion region 216. Further, the spacing 330 between the second diffusion region 218 and the fourth diffusion region 242 is reduced, which reduces the height of the cell 210 by allowing the bottom boundary of the cell 210 to be moved closer to the second diffusion region 218. In this example, the reduction in the spacings 310, 320, and 330 reduces the height of the cell 210 from H1 in FIG. 2A to H2 in FIG. 3. For comparison, both heights H1 and H2 are shown in FIG. 3.

However, reducing the spacings 310, 320, and 330 may significantly increase the risk of epi-epi shorts. For example, the widths of the epi layers in the y direction may vary due to process variation. As a result, the epi-epi spacing (i.e., spacing between adjacent epi layers) may need to be equal to or greater than a minimum spacing to ensure that process variation does not result in unintentional epi-epi shorts. The minimum spacing to avoid epi-epi shorts limits the ability to reduce the spacings 310, 320, and 330 to reduce the cell height.

To overcome the above limitations, aspects of the present disclosure provide a dielectric wall that electrically isolates adjacent epi layers, allowing the corresponding diffusion regions (i.e., active regions) to be spaced closer together to achieve cell height down scaling. In certain aspects, the dielectric wall is fabricated during backside processing after frontside processing used to fabricate transistors and topside metal layers (e.g., topside metal layers 140). As a result, fabrication of the dielectric wall does not interfere with frontside processing. This avoids complex process integration into the frontside process flow and improves manufacturability. The above features and other features of the present disclosure are discussed further below.

FIG. 4A shows a top view in which the chip 100 includes a first dielectric wall 410, a second dielectric wall 420, and a third dielectric wall 430 according to certain aspects. Each of the dielectric walls 410, 420, and 430 extends in the x direction, and the dielectric walls 410, 420, and 430 are spaced apart in the y direction. As used herein, a “dielectric wall” refers to a structure extending in the z-direction, and is made of substantially dielectric material, such as silicon dioxide (SiO2), silicon nitride (Si3N4), silicon carbon oxynitride (SiCON), etc. A dielectric wall may also be referred to as a dielectric barrier, dielectric isolation, an epi-epi dielectric wall, or another term. As discussed further below, each of the dielectric walls 410, 420, and 430 may be formed during backside processing by etching a trench from the backside of the chip 100 and filling the trench with dielectric material. In this example, a dielectric wall may also be referred to as a dielectric trench wall, a backside dielectric trench wall, or another term.

In this example, the first dielectric wall 410 is disposed between the first epi layer 222 and the second epi layer 226. The first dielectric wall 410 is also disposed between the third epi layer 224 and the fourth epi layer 228 on the other side of the gate 220. In this example, the first dielectric wall 410 may pass under the gate 220 with a portion of the gate 220 extending over the first dielectric wall 410 in the y direction to retain the shared gate between the first transistor 212 and the second transistor 214. However, it is to be appreciated that the present disclosure is not limited to this example. For example, the gate 220 may be cut into separate gates for the first transistor 212 and the second transistor 214 in implementations where the transistors 212 and 214 do not share a gate. In this example, the first dielectric wall 410 may pass between the separate gates for the first transistor 212 and the second transistor 214.

FIG. 4B shows a cross-sectional view taken along cross-section line Y1-Y2 in FIG. 4A, which intersects the first epi layer 222, the second epi layer 226, and the first dielectric wall 410. As shown in FIG. 4B, the first dielectric wall 410 is disposed between the first epi layer 222 and the second epi layer 226 to provide isolation between the first epi layer 222 and the second epi layer 226. The isolation prevents the first epi layer 222 and the second epi layer 226 from shorting, which allows the first diffusion region 216 and the second diffusion region 218 to be spaced closer together to scale down the height of the cell 210 without unintentionally shorting the first epi layer 222 and the second epi layer 226.

In the example shown in FIG. 4B, the first diffusion region 216 and the second diffusion region 218 are formed using a gate-all-around FET process, in which the first diffusion region 216 includes the channels 270 and the second diffusion region 218 includes the channels 275 discussed above with reference to FIG. 2C. However, it is to be appreciated that the present disclosure is not limited to this example.

In the example in FIG. 4B, the first dielectric wall 410 has a trapezoidal cross-sectional shape (i.e., profile) in which the first dielectric wall 410 tapers upward. As discussed further below, the upward tapering of the first dielectric wall 410 in this example is due to backside etching to form a trench for the first dielectric wall 410. However, it is to be appreciated that the first dielectric wall 410 is not limited to the exemplary shape shown in FIG. 4B. In the example shown in FIG. 4B, the first dielectric wall 410 has a first side 412 abutting the first epi layer 222 and a second side 414 abutting the second epi layer 226.

Returning to FIG. 4A, the second dielectric wall 420 is disposed between the first epi layer 222 and the fifth epi layer 236. The second dielectric wall 420 is also disposed between the third epi layer 224 and the sixth epi layer 238.

FIG. 4B shows a cross-sectional view taken along cross-section line Y1-Y2 in FIG. 4A, which intersects the first epi layer 222, the fifth epi layer 236, and the second dielectric wall 420. As shown in FIG. 4B, the second dielectric wall 420 is disposed between the first epi layer 222 and the fifth epi layer 236 to provide isolation between the first epi layer 222 and the fifth epi layer 236. The isolation prevents the first epi layer 222 and the fifth epi layer 236 from shorting, which allows the first diffusion region 216 and the third diffusion region 232 to be spaced closer together. The reduced spacing between the first diffusion region 216 and the third diffusion region 232 helps scale down the height of the cell 210 by allowing the top boundary of the cell 210 to be moved closer to the first diffusion region 216.

In the example shown in FIG. 4B, the first diffusion region 216 and the third diffusion region 232 are formed using a gate-all-around FET process, in which the first diffusion region 216 includes the channels 270 discussed above and the third diffusion region 232 includes the channels 440 (shown in FIG. 4C). The channels 440 are coupled to the fifth epi layer 236 shown in FIG. 4B. In FIG. 4B, the channels 440 are shown in dashed line to indicate the position of the channels 440 in the z and y direction. Note that the cross-section line Y1-Y2 does not intersect the gates 220, 234 and 244, and the channels 270 and 440.

In the example in FIG. 4B, the second dielectric wall 420 has a trapezoidal cross-sectional shape (i.e., profile) in which the second dielectric wall 420 tapers upward. As discussed further below, the upward tapering of the second dielectric wall 420 in this example is due to backside etching to form a trench for the second dielectric wall 420. However, it is to be appreciated that the second dielectric wall 420 is not limited to the exemplary shape shown in FIG. 4B. In the example shown in FIG. 4B, the second dielectric wall 420 has a first side 422 abutting the fifth epi layer 236 and a second side 424 abutting the first epi layer 222.

Returning to FIG. 4A, the third dielectric wall 430 is disposed between the second epi layer 226 and the seventh epi layer 246. The third dielectric wall 430 is also disposed between the fourth epi layer 228 and the eighth epi layer 248.

FIG. 4B shows a cross-sectional view taken along cross-section line Y1-Y2 in FIG. 4A, which intersects the second epi layer 226, the seventh epi layer 246, and the third dielectric wall 430. As shown in FIG. 4B, the third dielectric wall 430 is disposed between the second epi layer 226 and the seventh epi layer 246 to provide isolation between the second epi layer 226 and the seventh epi layer 246. The isolation prevents the second epi layer 226 and the seventh epi layer 246 from shorting, which allows the second diffusion region 218 and the fourth diffusion region 242 to be spaced closer together. The reduced spacing between the second diffusion region 218 and the fourth diffusion region 242 helps scale down the height of the cell 210 by allowing the bottom boundary of the cell 210 to be moved closer to the second diffusion region 218.

In the example shown in FIG. 4B, the second diffusion region 218 and the fourth diffusion region 242 are formed using a gate-all-around FET process, in which the second diffusion region 218 includes the channels 275 discussed above and the fourth diffusion region 242 includes the channels 450 (shown in FIG. 4C). The channels 450 are coupled to the seventh epi layer 246 shown in FIG. 4B. In FIG. 4B, the channels 450 are shown in dashed line to indicate the position of the channels 450 in the z and y direction. Note that the cross-section line Y1-Y2 does not intersect the gates 220, 234 and 244, and the channels 270 and 450.

In the example in FIG. 4B, the third dielectric wall 430 has a trapezoidal cross-sectional shape (i.e., profile) in which the third dielectric wall 430 tapers upward. As discussed further below, the upward tapering of the third dielectric wall 430 in this example is due to backside etching to form a trench for the third dielectric wall 430. However, it is to be appreciated that the third dielectric wall 430 is not limited to the exemplary shape shown in FIG. 4B. In the example shown in FIG. 4B, the third dielectric wall 430 has a first side 432 abutting the second epi layer 226 and a second side 434 abutting the seventh epi layer 246.

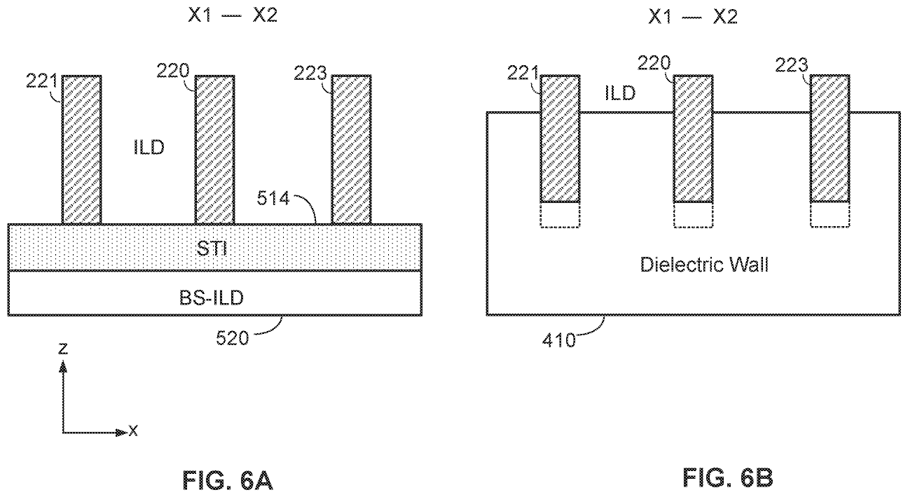

FIG. 4C shows a cross-sectional view taken along cross-section line Y3-Y4 in FIG. 2A. As shown in FIG. 4C, the channels 270 pass through the gate 220 and each of the channels 270 is surrounded by the gate 220 on four sides. The channels 275 pass through the gate 220 and each of the channels 275 is surrounded by the gate 220 on four sides. The channels 440 pass through the gate 234 and each of the channels 440 is surrounded by the gate 234 on four sides. The channels 450 pass through the gate 244 and each of the channels 450 is surrounded by the gate 244 on four sides. Note that the epi layers 222, 226, 236, and 246 are not intersected by the cross-section line Y3-Y4 in this example. In FIG. 4C, each of the epi layers 222, 226, 236, and 246 is shown in dashed line to indicate the position of the epi layer in the z and y direction. In some implementations, the height of the portion of the first dielectric wall 410 passing through the gate 220 may be shorter in the z direction than shown in FIG. 4C, as discussed further below with reference to FIGS. 6A and 6B.

Each of the channels 270, 275, 440, and 450 may include a respective nanosheet extending in direction x, a respective nanowire extending in direction x, or the like. In the example shown in FIG. 4B, the channels 270 are spaced apart in the z direction, the channels 275 are spaced apart in the z direction, the channels 440 are spaced apart in the z direction, and the channels 450 are spaced apart in the z direction. It is to be appreciated that the channels 270, 275, 440, and 450 are not limited to the exemplary cross-sectional shapes shown in the example in FIG. 4C, and may have other shapes in other implementations. In the example shown in FIG. 4C, each of the channels 270, 275, 440, and 450 includes three channels. However, it is to be appreciated that the present disclosure is not limited to this example. In general, each of the channels 270, 275, 440, and 450 includes one or more channels. For example, the channels 270 may include one or more first channels, and the channels 275 may include one or more second channels. As used herein, a “channel” is a structure that conducts current between a source and a drain of a transistor. For example, a channel may include a channel in a gate-all-around FET (e.g., a nanosheet, a nanowire, etc.), a fin in a FinFET, or another type of channel.

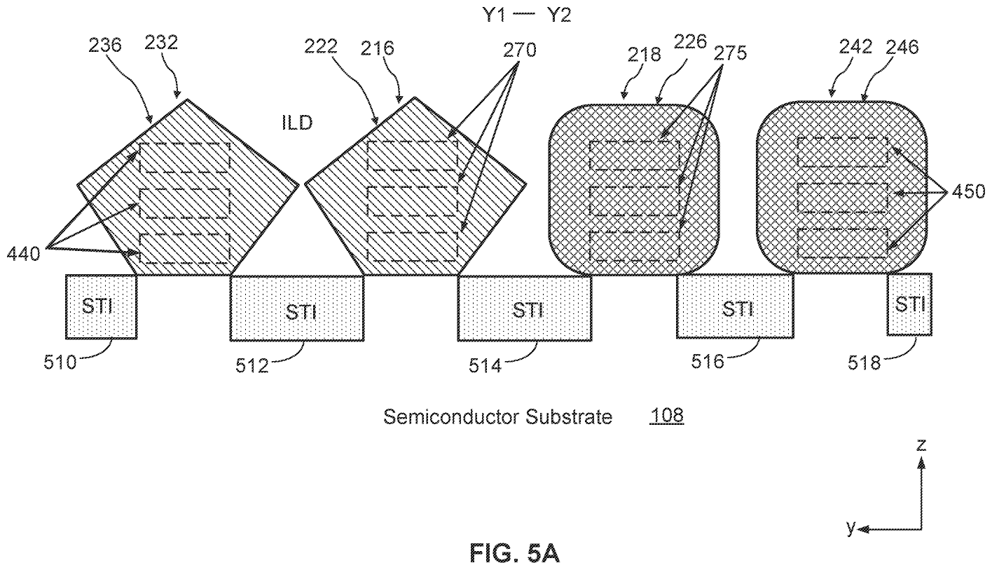

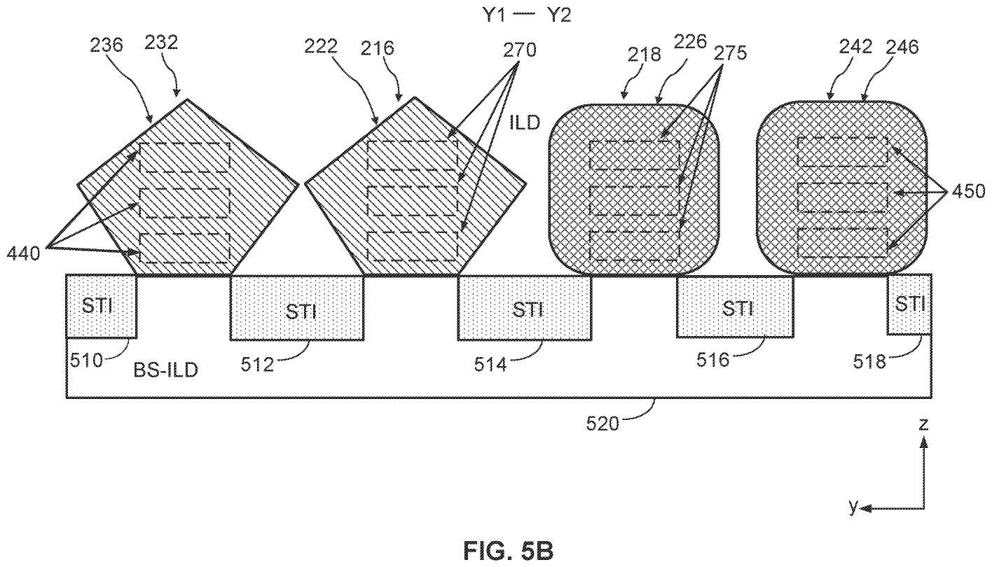

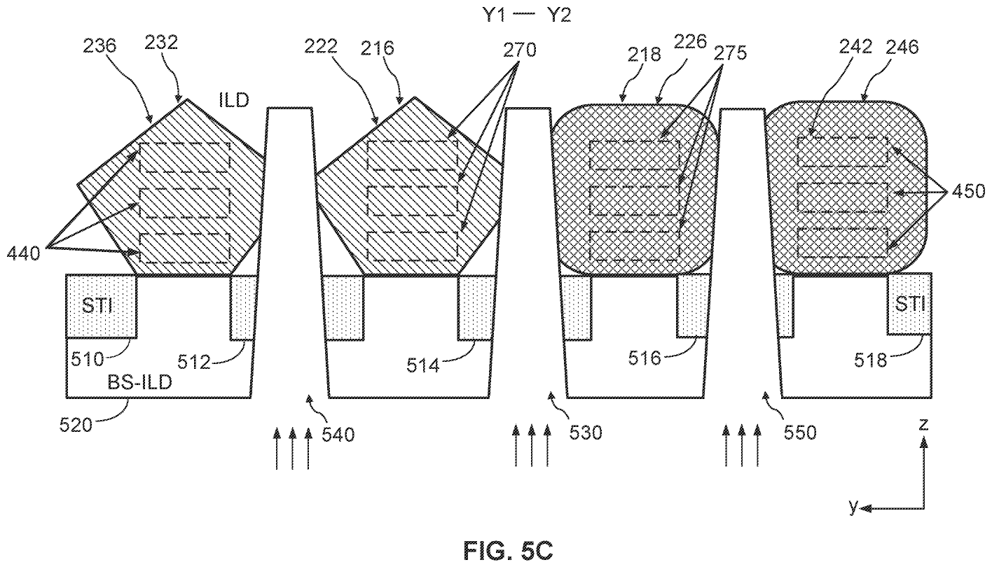

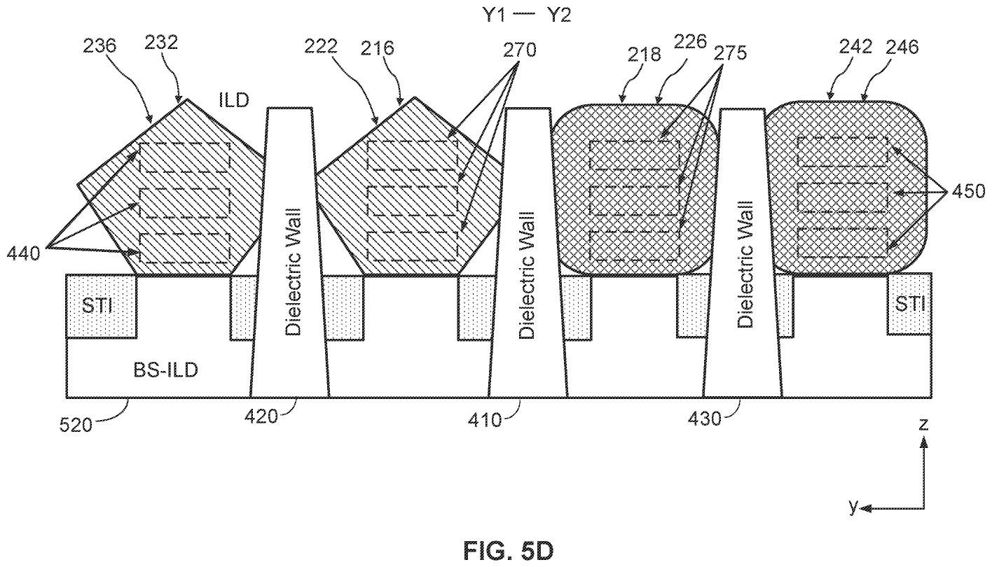

An exemplary process flow for fabricating the dielectric walls 410, 420, and 430 will now be described according to certain aspects with reference to FIGS. 5A to 5C. As discussed further below, the dielectric walls 410, 420, and 430 are formed during backside processing, which avoids complex process integration into the frontside process flow and improves manufacturability.

FIG. 5A shows a cross-sectional view of the epi layers 222, 226, 236, and 246 after frontside processing taken along cross-section line Y1-Y2. The frontside processing includes formation of the transistors 212, 214, 230, and 240 on the semiconductor substrate 108 (e.g., silicon substrate) and formation of the topside metal layers (e.g., metal layers M0, M1, etc.) above the transistors 212, 214, 230, and 240. The formation of the transistors 212, 214, 230, and 240 includes formation of the channels 270, 275, 440, and 450, the gates 220, 221, 223, 234, 231, 233, 244, 241, and 243, and the epi layers 222, 224, 226, 228, 236, 238, 246, and 248. The frontside processing may also include formation of shallow trench isolation (STI) regions 510, 512, 514, 516, and 518, as shown in the example in FIG. 5A. In some implementations, the STI regions 510, 512, 514, 516, and 518 may be omitted. The frontside processing may also include filling the space (i.e., gaps) between the epi layers 222, 224, 226, 228, 236, 238, 246, and 248 with an interlayer dielectric (ILD). It is to be appreciated that the frontside processing may include one or more additional process steps in addition to the ones discussed above. Note that the gates 220, 234, and 242 and the epi layers 224, 228, 238, and 248 are not shown in FIG. 5A since the cross-section line Y1-Y2 does not intersect the gates 220, 234, and 242 and the epi layers 224, 228, 238, and 248 in this example.

It is to be appreciated that the epi layers 222, 226, 236, and 246 may be spaced closer together than shown in the example in FIG. 5A. For example, in some cases, the adjacent tips of the first epi layer 222 and the fifth epi layer 236 may touch. In this example, the second dielectric wall 420 (which is formed later during backside processing) will isolate the first epi layer 222 and the fifth epi layer 236 to prevent shorting of the first epi layer 222 and the fifth epi layer 236.

After the frontside processing discussed above, a carrier wafer (not shown) may be bonded to the top of the chip 100 for structural support. The chip 100 may be flipped to expose the backside of the semiconductor substrate 108, and most or all of the semiconductor substrate 108 (e.g., silicon substrate) may be removed. For example, the semiconductor substrate 108 may be removed using a combination of backside grinding, chemical mechanical polishing (CMP), and/or etching.

FIG. 5B shows a cross-sectional view of the epi layers 222, 226, 236, and 246 after removal of the semiconductor substrate 108. In this example, a thin backside interlayer dielectric (BS-ILD) 520 is formed on the backside of the chip 100. The BS-ILD 520 may fill the spaces under the diffusion regions 216, 218, 232, and 242 between the STI regions 510, 512, 514, 516, and 518, as shown in the example in FIG. 5B.

After formation of the BS-ILD 520, a first trench 530, a second trench 540, and a third trench 550 are etched into the chip 100 from the backside, as shown in FIG. 5C. The areas of the chip 100 that are etched to form the trenches 530, 540, and 550 (i.e., trench patterning) may be selected using a lithographic process and/or another technique.

The etching process may include a reactive ion etching process, a plasma etching process, and/or another type of suitable etching process. In FIG. 5C, the direction of the etching is indicated by the arrows pointing into the openings of the trenches 530, 540, and 550. As shown in FIG. 5C, the etching process etches through the BS-ILD 520, the STI regions 512, 514, and 516, and the ILD to form the trenches 530, 540, and 550. The etching process may also etch through (i.e., cut through) portions of the epi layers 222, 224, 236, and 246, as discussed further below.

In this example, each of the trenches 530, 540, and 550 has a tapered profile (i.e., tapered cross section) that tapers upward since the etching is done from the backside of the chip 100. In other words, the width of each of the trenches 530, 540, and 550 in the y direction narrows in the upward direction. As used herein, the “upward direction” is a direction pointing from the backside layers 155 to the topside layers 105 in the z direction. In this example, the trenches 530, 540, and 550 may also be referred to as backside trenches since the trenches 530, 540, and 550 are formed from the backside.

In the example in FIG. 5C, the first trench 530 is between the first epi layer 222 and the second epi layer 226, and cuts through a portion of the first epi layer 222 and a portion of the second epi layer 226. In cases where the adjacent sides of the first epi layer 222 and the second epi layer 226 touch before the backside etching to form the first trench 530, the backside etching etches away the portions of the epi layers 222 and 226 that are touching, thereby isolating the epi layers 222 and 226. The first trench 530 may also extend in the x direction between the third epi layer 224 and the fourth epi layer 228 (not shown in FIG. 5C).

The second trench 540 is between the first epi layer 222 and the fifth epi layer 236, and cuts through a portion of the first epi layer 222 and a portion of the fifth epi layer 236. In cases where the adjacent sides of the first epi layer 222 and the fifth epi layer 236 touch before the backside etching to form the second trench 540, the backside etching etches away the portions of the epi layers 222 and 236 that are touching, thereby isolating the epi layers 222 and 236. The second trench 540 may also extend in the x direction between the sixth epi layer 238 and the third epi layer 224 (not shown in FIG. 5C).

The third trench 550 is between the second epi layer 226 and the seventh epi layer 246, and cuts through a portion of the second epi layer 226 and a portion of the seventh epi layer 246. In cases where the adjacent sides of the second epi layer 226 and the seventh epi layer 246 touch before the backside etching to form the third trench 550, the backside etching etches away the portions of the epi layers 226 and 246 that are touching, thereby isolating the epi layers 226 and 246. The third trench 550 may also extend in the x direction between the fourth epi layer 228 and the eighth epi layer 248 (not shown in FIG. 5C).

After formation of the trenches 530, 540, 540, the first trench 530, the second trench 540, and the third trench 550 are filled with dielectric material to form the first dielectric wall 410, the second dielectric wall 420, and the third dielectric wall 430, respectively, as shown in FIG. 5D. The dielectric material may include one or more of the following: silicon dioxide (SiO2), silicon nitride (Si3N4), silicon carbon oxynitride (SiCON), etc.

After formation of the dielectric walls 410, 420, and 430, the backside contacts (e.g., backside contacts 158, 252, and 256) may be formed. Also, the backside metal layer BM0 may be formed and patterned to form backside rails (e.g., backside rails 250 and 254). In addition, the remaining backside metal layers may be formed and patterned (e.g., to form one or more backside power distribution networks).

FIG. 6A shows a cross-sectional view taken along cross-section line X1-X2 in FIG. 4A, which intersects the gates 221, 220, and 223. The cross-sectional view shown in FIG. 6A is after removal of most or all of the semiconductor substrate 108, after formation of the BS-ILD 520 discussed above with reference to FIG. 5B, and before formation of the first dielectric wall 410.

FIG. 6B shows the cross-sectional view along the cross-section line X1-X2 after formation of the first dielectric wall 410. As shown in FIG. 6B, the backside etching process for etching the trench 530 for the first dielectric wall 410 etches away the BS-ILD 520, the STI region 514, and a portion of the ILD shown in FIG. 6A.

In this example, the backside etching process may also etch away portions of the gates 221, 220, and 223. In FIG. 6B, the portions of the gates 221, 220, and 223 that are etched away are shown in dotted line. In this example, the etching process may use etchant(s) that selectively etch away the BS-ILD 520, the STI region 514, and the ILD to form the trench 530 while minimizing etching of the gate material (e.g., HKMG) of the gates 221, 220, and 223. Examples of etchants that may be used include hydrofluoric acid (HF), tetramethylammonium hydroxide (TMAH), ammonium fluoride (NH4F), phosphoric acid (H3PO4), potassium hydroxide (KOH), etc.

In this example, most of the gate 220 remains after the backside etching process, retaining the shared gate of the first transistor 212 and the second transistor 214. In other words, only a portion of the gate 220 is etched away to preserve the shared gate. In this example, the first dielectric wall 410 passes under the gate 220 in the x direction. The first dielectric wall 410 also extends between the epi layers 222 and 226 in the x direction on one side of the gate 220 and extends between the epi layers 224 and 228 in the x direction on the other side of the gate 220 (shown in FIG. 4A).

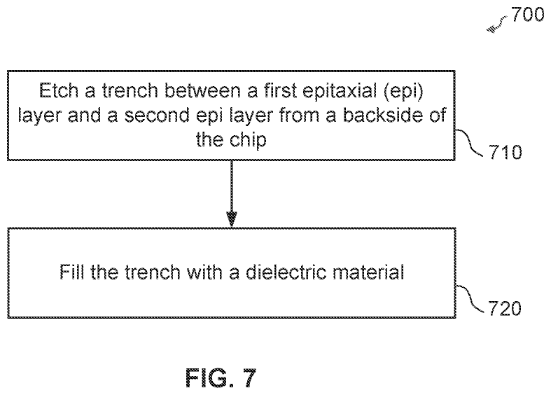

FIG. 7 shows an exemplary method 700 of fabricating a dielectric wall on a chip. The dielectric wall may be any one of the exemplary dielectric walls 410, 420, and 430 discussed above.

At block 710, a trench is etched between a first epitaxial (epi) layer and a second epi layer from a backside of the chip. For example, the trench may correspond to the trench 530, the first epi layer may correspond to the first epi layer 222, and the second epi layer may correspond to the second epi layer 226.

At block 720, the trench is filled with a dielectric material. For example, the dielectric material may include an oxide or another dielectric material.

In certain aspects, etching the trench includes etching away a portion of the first epi layer and a portion of the second epi layer. For example, the portion of the first epi layer and the portion of the second epi layer may touch.

In certain aspects, etching the trench includes etching through an interlayer dielectric (ILD) between the first epi layer and the second epi layer. For example, the ILD may correspond to the ILD shown in FIG. 5B between the first epi layer 222 and the second epi layer 226.

In certain aspects, the method 700 also includes forming multiple topside metal layers above the first epi layer and the second epi layer, and removing most or all of a semiconductor substrate of the chip after forming the multiple topside metal layers and before etching the trench. For example, the topside metal layers may correspond to the topside metal layers 140, and the semiconductor substrate may correspond to the semiconductor substrate 108 (e.g., silicon substrate). Removing most or all of the semiconductor substrate may include backside grinding and chemical mechanical polishing (CMP). As used herein, “most or all” means at least 90 percent.

The method 700 may also include forming a backside interlayer dielectric layer (ILD) beneath the first epi layer and the second epi layer after removing most or all of the semiconductor substrate, wherein etching the trench includes etching through the backside ILD. The backside ILD may correspond to the BS-ILD shown in FIG. 5C.

Implementation examples are described in the following numbered clauses:

1. A chip, comprising:
one or more first channels extending in a first direction;
a first epitaxial (epi) layer coupled to the one or more first channels;
one or more second channels extending in the first direction;
a second epi layer coupled to the one or more second channels; and
a dielectric wall disposed between the first epi layer and the second epi layer.

2. The chip of clause 1, wherein the dielectric wall has a trapezoidal profile.

3. The chip of clause 2, wherein the dielectric wall tapers upward.

4. The chip of any one of clauses 1 to 3, wherein the first epi layer abuts a first side of the dielectric wall, and the second epi layer abuts a second side of the dielectric wall.

5. The chip of any one of clauses 1 to 4, further comprising a gate extending in a second direction perpendicular to the first direction, wherein the one or more first channels pass through the gate.

6. The chip of clause 5, wherein the one or more second channels pass through the gate.

7. The chip of clause 5 or 6, wherein the dielectric wall extends in the first direction and passes under the gate.

8. The chip of clause 7, further comprising:
a third epi layer coupled to the one or more first channels, wherein the gate is
between the first epi layer and the third epi layer; and
a fourth epi layer coupled to the one or more second channels, wherein the gate is between the second epi layer and the fourth epi layer, and the dielectric wall is disposed between the third epi layer and the fourth epi layer.

9. The chip of any one of clauses 1 to 8, further comprising:
a first backside contact coupled to a back surface of the first epi layer; and
a second backside contact coupled to a back surface of the second epi layer, wherein the dielectric wall is disposed between the first backside contact and the second backside contact.

10. The chip of clause 9, further comprising:
a first rail formed from a backside metal layer, wherein the first rail is coupled to the first backside contact; and
a second rail formed from the backside metal layer, wherein the second rail is coupled to the second backside contact.

11. The chip of clause 10, wherein the first rail is a supply rail and the second rail is a ground rail.

12. The chip of clause 10 or 11, wherein the first rail extends in the first direction, the second rail extends in the first direction, and the first rail and the second rail are spaced apart in a second direction perpendicular to the first direction.

13. The chip of any one of clauses 1 to 12, wherein the dielectric wall comprises at least one of silicon dioxide (SiO2), silicon nitride (Si3N4), and silicon carbon oxynitride (SiCON).

14. The chip of any one of clauses 1 to 13, wherein the chip includes a backside interlayer dielectric (ILD) beneath the first epi layer and the second epi layer, and the dielectric wall extends through at least a portion of the backside ILD.

15. A method of fabricating a dielectric wall on a chip, comprising:
etching a trench between a first epitaxial (epi) layer and a second epi layer from a backside of the chip; and
filling the trench with a dielectric material.

16. The method of clause 15, wherein etching the trench comprises etching away a portion of the first epi layer and a portion of the second epi layer.

17. The method of clause 15 or 16, wherein etching the trench comprises etching through an interlayer dielectric (ILD) between the first epi layer and the second epi layer.

18. The method of any one of clauses 15 to 17, further comprising:
forming multiple topside metal layers above the first epi layer and the second epi layer; and
removing most or all of a semiconductor substrate of the chip after forming the multiple topside metal layers and before etching the trench.

19. The method of clause 18, further comprising forming a backside interlayer dielectric layer (ILD) beneath the first epi layer and the second epi layer after removing most or all of the semiconductor substrate, wherein etching the trench comprises etching through the backside ILD.

20. The method of any one of clauses 15 to 19, wherein the dielectric material comprises at least one of silicon dioxide (SiO2), silicon nitride (Si3N4), and silicon carbon oxynitride (SiCON).

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
one or more first channels extending in a first direction;
a first epitaxial (epi) layer coupled to the one or more first channels;
one or more second channels extending in the first direction;
a second epi layer coupled to the one or more second channels; and
a dielectric wall disposed between the first epi layer and the second epi layer.

2. The chip of claim 1, wherein the dielectric wall has a trapezoidal profile.

3. The chip of claim 2, wherein the dielectric wall tapers upward.

4. The chip of claim 1, wherein the first epi layer abuts a first side of the dielectric wall, and the second epi layer abuts a second side of the dielectric wall.

5. The chip of claim 1, further comprising a gate extending in a second direction perpendicular to the first direction, wherein the one or more first channels pass through the gate.

6. The chip of claim 5, wherein the one or more second channels pass through the gate.

7. The chip of claim 5, wherein the dielectric wall extends in the first direction and passes under the gate.

8. The chip of claim 7, further comprising:
a third epi layer coupled to the one or more first channels, wherein the gate is between the first epi layer and the third epi layer; and
a fourth epi layer coupled to the one or more second channels, wherein the gate is between the second epi layer and the fourth epi layer, and the dielectric wall is disposed between the third epi layer and the fourth epi layer.

9. The chip of claim 1, further comprising:
a first backside contact coupled to a back surface of the first epi layer; and
a second backside contact coupled to a back surface of the second epi layer, wherein the dielectric wall is disposed between the first backside contact and the second backside contact.

10. The chip of claim 9, further comprising:
a first rail formed from a backside metal layer, wherein the first rail is coupled to the first backside contact; and
a second rail formed from the backside metal layer, wherein the second rail is coupled to the second backside contact.

11. The chip of claim 10, wherein the first rail is a supply rail and the second rail is a ground rail.

12. The chip of claim 10, wherein the first rail extends in the first direction, the second rail extends in the first direction, and the first rail and the second rail are spaced apart in a second direction perpendicular to the first direction.

13. The chip of claim 1, wherein the dielectric wall comprises at least one of silicon dioxide (SiO2), silicon nitride (Si3N4), and silicon carbon oxynitride (SiCON).

14. The chip of claim 1, wherein the chip includes a backside interlayer dielectric (ILD) beneath the first epi layer and the second epi layer, and the dielectric wall extends through at least a portion of the backside ILD.

15. A method of fabricating a dielectric wall on a chip, comprising:
etching a trench between a first epitaxial (epi) layer and a second epi layer from a backside of the chip; and
filling the trench with a dielectric material.

16. The method of claim 15, wherein etching the trench comprises etching away a portion of the first epi layer and a portion of the second epi layer.

17. The method of claim 15, wherein etching the trench comprises etching through an interlayer dielectric (ILD) between the first epi layer and the second epi layer.

18. The method of claim 15, further comprising:
forming multiple topside metal layers above the first epi layer and the second epi layer; and
removing most or all of a semiconductor substrate of the chip after forming the multiple topside metal layers and before etching the trench.

19. The method of claim 18, further comprising forming a backside interlayer dielectric layer (ILD) beneath the first epi layer and the second epi layer after removing most or all of the semiconductor substrate, wherein etching the trench comprises etching through the backside ILD.

20. The method of claim 15, wherein the dielectric material comprises at least one of silicon dioxide (SiO2), silicon nitride (Si3N4), and silicon carbon oxynitride (SiCON).
